(19) United States
(12) Patent Application Publication
(10) Pub. No.: US 2014/0076956 A1
(43) Pub. Date: Mar. 20, 2014

(54) SOLDERING MACHINE AND METHOD OF SOLDERING

(71) Applicant: TYCO ELECTRONICS CORPORATION, Berwyn, PA (US)

(72) Inventors: Roberto Francisco-Yi Lu, Bellevue, WA (US); Qinglong Zeng, Shenzhen (CN); Charles David Fry, New Bloomfield, PA (US); Bicheng Chen, Harrisburg, PA (US)

(73) Assignee: Tyco Electronics Corporation, Berwyn, PA (US)

(21) Appl. No.: 13/833,114

(22) Filed: Mar. 15, 2013

Related U.S. Application Data
(60) Provisional application No. 61/703,372, filed on Sep. 20, 2012.

(51) Int. Cl. H05K 13/06

(52) U.S. Cl. CPC H05K 13/06
USPC 228/102; 228/8

(57) ABSTRACT

A soldering machine includes a frame and a fixture held by the frame that supports a substrate and a cable. A guidance system is supported by the frame with a camera viewing the fixture that is movable relative to the fixture. A positioning system is supported by the frame. The positioning system has a camera positioner and a soldering mechanism positioner. A soldering mechanism is coupled to the soldering mechanism positioner and is moved by the soldering mechanism positioner relative to the fixture. The soldering mechanism solders wires to the substrate. A controller communicates with the positioning system and the guidance system to operates the positing system to control positions of the camera and soldering mechanism relative to the fixture based on an image obtained by the camera.

### CROSS REFERENCE TO RELATED APPLICATIONS

This application claims the benefit of U.S. Provisional Application No. 61/703,372 filed Sep. 20, 2012, the subject matter of which is herein incorporated by reference in its entirety.

### BACKGROUND OF THE INVENTION

The subject matter herein relates generally to soldering machines and methods of soldering.

Many electrical components are manufactured by soldering various components together. For example, wires may be soldered to conductive traces on a circuit board. The soldering is performed by a soldering mechanism that joins the wire and conductive traces by melting and flowing solder into the joint therebetween. Soldering may be performed manually or by an automated process. Manual application is time consuming and increases the expense of the electrical component. Soldering quality is a problem with manual soldering. Automated processes also have disadvantages. For example, the automated process uses a preprogrammed control that does not take into account for the actual positions of the components. Also, because the automated process does not have feedback during the application, the preprogrammed application has strict requirements on tolerances of soldering fixture dimensions. Because of the tolerances on the dimensions of the soldering fixture, the soldering accuracy is limited, leading to rework of the part to pass quality checks.

There is a need for a cost effective automated process of soldering without human operator intervention.

### BRIEF DESCRIPTION OF THE INVENTION

In one embodiment, a soldering machine is provided including a frame and a fixture held by the frame. The fixture is configured to support a substrate and a cable with individual wires configured to be soldered to conductive traces of the substrate. A guidance system is supported by the frame. The guidance system has a camera viewing the fixture that is movable relative to the fixture. A positioning system is supported by the frame. The positioning system has a camera positioner and a soldering mechanism positioner. The camera is coupled to and movable by the camera positioner relative to the fixture. A soldering mechanism is coupled to the soldering mechanism positioner and is moved by the soldering mechanism positioner relative to the fixture. The soldering mechanism is configured to solder the wires to the conductive traces of the substrate. A controller communicates with the positioning system and the guidance system. The controller operates the positing system to control a position of the camera and a position of the soldering mechanism relative to the fixture based on an image obtained by the camera.

In another embodiment, a method of soldering a wire to a conductive trace of a substrate includes holding the substrate on a fixture, holding the wire relative to the substrate, capturing an image of the wire and the substrate using a camera, developing a motion profile based on the position of the wire and the substrate from the image using a controller, and moving a soldering mechanism to solder the wire to the conductive trace on the substrate based on the motion profile.

### BRIEF DESCRIPTION OF THE DRAWINGS

FIG. 1 illustrates a soldering machine formed in accordance with an exemplary embodiment.

FIG. 2 is an enlarged view of a soldering mechanism and soldering mechanism positioner of the soldering machine.

FIG. 3 is an enlarged view of a solder wire delivery mechanism of the soldering machine.

FIG. 4 is an enlarged view of a camera, a portion of a camera positioner, a holder and a holder positioner all of the soldering machine.

FIG. 5 illustrates a fixture of the soldering machine.

FIG. 6 is an enlarged view of a portion of the soldering machine showing the soldering mechanism soldering a wires to a corresponding substrate.

FIG. 7 illustrates a method of soldering a wire to a substrate.

### DETAILED DESCRIPTION OF THE INVENTION

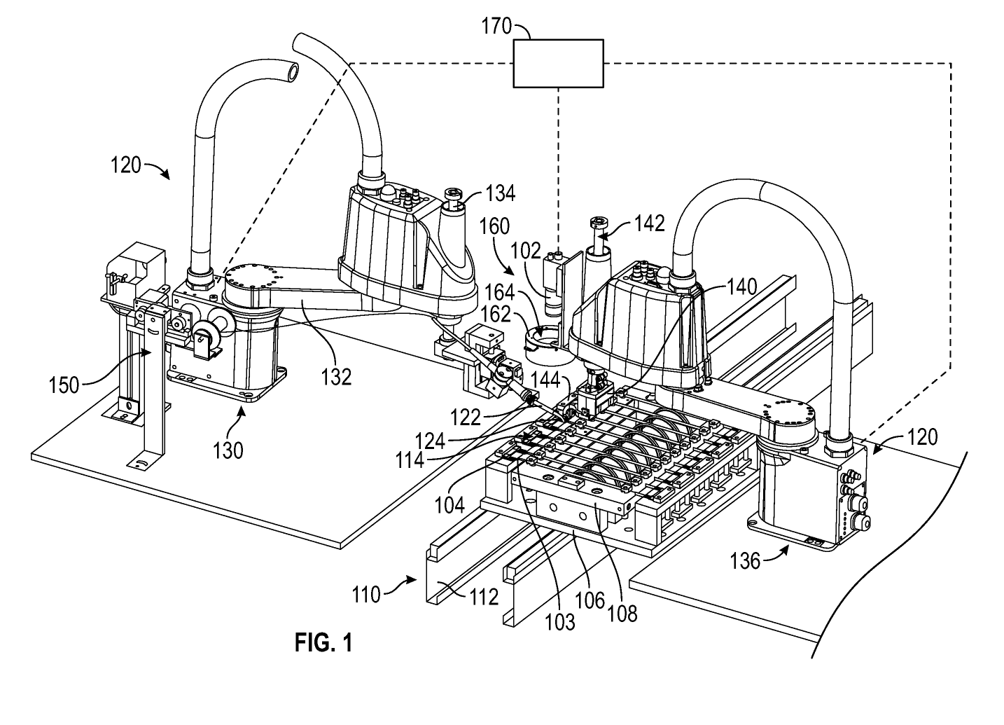

FIG. 1 illustrates a soldering machine 100 formed in accordance with an exemplary embodiment. The soldering machine 100 is used for soldering wires 103 onto corresponding conductive traces of a substrate 104. The substrate 104 may be a circuit board or other type of electrical component having conductive traces thereon. The soldering machine 100 automatically solders the wires 103 to the substrates 104 by an automated process using computer control.

The soldering machine 100 provides vision guidance using an optical image sensor, referred to herein as a camera 102, to collect images and data relating to the wires 103, to the substrates 104, to any components of the substrate 104 (e.g. conductive traces), to any dispensed fluid on the substrate 104, to the location of the soldering mechanism, and the like. The soldering machine 100 dynamically changes parameters and control of the components of the soldering machine 100 based on the images. For example, the parameters and control may be based on geometrical characteristic data obtained based upon the image captured by the camera 102. Any wire 103 or substrate 104 presented to the soldering machine 100 may have different characteristics, such as a different position of the wire relative to the conductive trace, a different layout of conductive traces, different positioning relative to the soldering mechanism, or other characteristics that may be identified and accommodated for using vision guidance. The soldering machine 100 identifies specific characteristics of the wires 103 and the substrate 104 and properly positions the soldering mechanism relative to the wires 103 and the substrate 104 for performing the soldering operation.

In the illustrated embodiment, the soldering machine 100 processes a plurality of substrates 104. The substrates 104 are held on a fixture 106 and the wires 103 are held on a tray 108 of the fixture 106. The tray 108 may be removable from the fixture 106. For example, the cables and wires 103 may be positioned on the tray 108 during a separate manufacturing process, such as at a different station using a different machine, such as a wire sorting machine that automatically positions the wires in proper positions for soldering to the substrates 104 without further human intervention. The tray 108 is then coupled to the fixture 106 to position the wires 103 relative to the substrates 104. Optionally, the substrates 104 may be preprocessed during a separate manufacturing process, such as at a different station using a different machine, such as a fluid dispensing machine where engineering fluid (e.g. solder) is dispensed on the conductive traces so the substrates 104 are ready for soldering. Any number of wires 103 and substrates 104 may be held by the fixture 106 and presented to the soldering machine 100 as a batch. Alternatively, the substrates 104 and corresponding wires 103 may be individually presented to the soldering machine 100 rather than being presented as a batch as part of the fixture 106.

The soldering machine 100 includes a frame 110 that supports the various components of the soldering machine 100. The frame 110 may be stationary. The frame 110 may be part of a larger machine, such as positioned at a station before or after other stations. In an exemplary embodiment, the frame 110 includes a track 112. The fixture 106 may be conveyed along the track 112. Optionally, once the fixture 106 is positioned in a working zone 114 of the soldering machine 100, the fixture 106 may be held in place and restricted from moving along the track 112.

The soldering machine 100 includes a positioning system 120 supported by the frame 110. The positioning system 120 is used to position the camera 102 relative to the fixture 106 during operation of the soldering machine 100. The positioning system 120 is used to position a soldering mechanism 122 relative to the fixture 106 during operation of the soldering machine 100. In an exemplary embodiment, the positioning system 120 is a Cartesian motion robot with rotary axis. Other types of systems may be used in other embodiments, such as a selective compliance assembly robot arm (SCARA) or other robotic motion system.

The soldering mechanism 122 is used to reflow solder between the substrate 104 and the corresponding wire 103. The soldering mechanism 122 is movable in three dimensions according to a particular motion profile and process parameters determined by the soldering machine 100 based on the particular arrangement of the wires 103 and the substrates 104. Optionally, a tip 124 of the soldering mechanism 122 is moved in proximity to the wires 103 and the substrates 104 to reflow the solder therebetween. Optionally, the soldering mechanism 122 may dispense solder between the wires 103 and substrates 104 during the soldering process. In an exemplary embodiment, a sensor may be provided on or in the soldering mechanism 122 for measuring force, such as when the soldering mechanism 122 is pressed into the solder, the substrate and/or the wire. The force measurement may be used to verify positioning of the soldering mechanism. The positioning system 120 may use the force measurement to control positioning of the soldering mechanism 122. For example, the heating may be controlled based on the force measurement (e.g. more force may correspond to better heat conduction and more heat being transferred to the solder, the substrate and/or the wire). The force sensor may be a strain gauge or other type of force sensor. The force sensor may be internal or external mounted. The force sensor may be provided proximate to the tip 124 or remote from the tip 124.

Optionally, the soldering mechanism 122 may be positioned on the frame 110 independently of the camera 102, such as using different positioners. The camera 102 may be movable independent of the soldering mechanism 122 according to a particular motion profile determined by the soldering machine 100 based on the particular arrangement of the wires 103 and the substrates 104. Optionally, the camera 102 may be movable in two dimensions, such as along a horizontal plane. Alternatively, the camera 102 may be movable in three dimensions. Optionally, multiple cameras may be provided for viewing the soldering region from different angles. For example, one camera may view the region from vertically above while another camera may view the region from the side.

A coordinate system is illustrated in FIG. 1 showing mutually perpendicular X, Y and Z axes. In an exemplary embodiment, the positioning system 120 includes a soldering mechanism positioner 130 that controls an X position, a Y position and a Z position of the soldering mechanism 122. In the illustrated embodiment, the soldering mechanism positioner 130 includes a rotary arm 132 that controls the X and Y positions of the soldering mechanism 122 and a Z positioner 134 that controls the Z position of the soldering mechanism 122. Other types of positioners may be used in other embodiments. Optionally, the soldering mechanism positioner 130 may include at least one angular positioner to allow angular movement of components of the soldering machine 100 in three dimensional space.

In an exemplary embodiment, the positioning system 120 includes a camera positioner 136 that controls an X position and a Y position of the camera 102. In the illustrated embodiment, the camera positioner 136 includes a rotary arm 132 that controls the X and Y positions of the camera 102. Other types of positioners may be used in alternative embodiments. For example, a Z positioner or an angular positioner may be used to change a Z position or an angular position of the camera 102.

In an exemplary embodiment, the soldering machine 100 includes a holder 140 that is used to hold the wires 103 during soldering. The holder 140 may be independently movable relative to the soldering mechanism 122 and/or the camera 102. The positioning system 120 includes a holder positioner 142 that controls an X position, a Y position and/or a Z position of the soldering mechanism 122. In the illustrated embodiment, the holder positioner 142 is coupled to the camera positioner 136. The holder 140 is movable with the camera 102 using the camera positioner 136. The holder positioner 142 is a Z-positioner that allows independent vertical movement of the holder 140 relative to the camera 102. Other configurations are possible in alternative embodiments. The holder 140 includes a finger 144 that may be positioned vertically below the camera 102 at a position to engage and hold a corresponding wire 103 that is in view of the camera 102. The holder 140 holds the wire 103 during the soldering process.

In an exemplary embodiment, the soldering machine 100 includes a solder wire delivery mechanism 150. The solder wire delivery mechanism 150 delivers solder wire to the soldering mechanism 122. The solder wire delivery mechanism 150 includes integrated sensors to control the delivery amount of soldering material. The solder wire delivery mechanism 150 includes an anti-oxidant mechanism to maintain the cleanness of the solder iron tip. The solder wire delivery mechanism 150 includes an integrated temperature sensor for providing temperature feedback to the soldering machine 100. A force sensor may be provided for measure forces, such as when the soldering mechanism 122 touches the solder, the substrate and/or the wire.

The soldering machine 100 includes a guidance system 160 that provides visual guidance for the soldering process. The camera 102 forms part of the guidance system 160. The camera 102 is aimed at the work zone 114 and takes images of the wire 103, the substrate 104 and/or the soldering mechanism 122. Optionally, the camera 102 may take continuous images and the soldering machine 100 may continuously update operation based on such images. Alternatively, the camera 102 may take images at predetermined times, such as at each new substrate location prior to soldering, at various stages of the soldering process (e.g. after each wire is soldered), at predetermined times intervals (e.g. 1 image per second), and the like. The guidance system 160 may include, or receive input from, a force sensor or another type of sensor.

In an exemplary embodiment, the guidance system 160 includes an optical component 162 for controlling optical characteristics of the soldering machine 100. For example, the optical component 162 may include an illumination source for illuminating the work zone 114, soldering mechanism 122, wire 103 and/or the substrate 104. The illumination source may emit lights at different wavelengths on the work zone 114 to facilitate identification of characteristics of the solder joint, the wire 103, the substrate 104, the boundary between the wire 103 and the substrate 104, the solder at the boundary, and the like. The different light wavelengths may be used to distinguish the wire 103 from the substrate 104.

The soldering machine 100 includes a controller 170 that controls operation of the soldering machine 100. The controller 170 communicates with the solder wire delivery mechanism 150 and receives inputs from the sensors of the solder wire delivery mechanism 150 that may be used to control operation of the soldering machine 100. The controller 170 communicates with the positioning system 120 and the guidance system 160. For example, the images generated by the camera 102 are processed by the controller 170. The controller 170 includes a motion planning and process parameter calculation algorithm. The controller 170 may provide motion planning for the soldering mechanism 122, the camera 102 and/or the holder 140. For example, the controller 170 may include a soldering mechanism motion planning algorithm that formulates a motion profile that controls operation of the positioning system 120 to control motion of the soldering mechanism 122. The controller 170 may include a camera motion planning algorithm that formulates a motion profile that controls operation of the positioning system 120 to control motion of the camera 102. The controller 170 may include a holder motion planning algorithm that formulates a motion profile that controls operation of the positioning system 120 to control motion of the holder 140. The controller 170 may define process parameters, such as the amount of energy to use at the soldering mechanism, the rate of soldering, the zoom or focus of the camera, the action of the holder, and the like. The controller 170 may have other inputs other than the images from the camera 102, such as temperature inputs from the tip of the soldering mechanism 122.

The motion planning algorithms are based on the images provided by the camera 102. The controller 170 identifies each location where soldering is to occur, including the shape and location of the wire 103 relative to the conductive trace. The controller 170 determines a plan for moving the soldering mechanism 122 to the necessary locations. The controller 170 calculates a series of movements for the positioning system 120 to efficiently move the soldering mechanism 122 to the necessary locations. The controller 170 determines a plan for moving the camera 102 to the necessary locations. The camera 102 position may change during the soldering process. The controller 170 calculates a series of movements for the positioning system 120 to efficiently move the camera 102 to the necessary locations. The controller 170 determines a plan for moving the holder 140 to the necessary locations. The location of the holder 140 may be dependent on the location of the wire 103, which may vary from station to station. The controller 170 calculates a series of movements for the positioning system 120 to efficiently move the holder 140 to the necessary locations.

In an exemplary embodiment, the illumination source emits the lights onto the wires 103 and the substrate 104 to assist the controller 170 in identifying the characteristics of the substrate 104. The identification process may be based on the intensity of the data points in the image. For example, different materials (e.g. plastic, metal, solder) may have different intensity levels in the image, which aids the controller 170 in identifying boundaries between the different materials.

The controller 170 controls the X, Y, Z and/or angular position of the soldering mechanism 122 during operation of the soldering machine 100. The controller 170 controls the X, Y, Z and/or angular position of the camera 102 during operation of the soldering machine 100. The controller 170 controls the X, Y, Z and/or angular position of the holder 140 during operation of the soldering machine 100. The controller 170 uses the motion planning algorithm to develop a motion profile for positioning the soldering mechanism 122 relative to the wire 103 and the substrate 104. In operation, the controller 170 positions the camera 102 and soldering mechanism 122 at a series of stations, where a substrate 104 and corresponding wires 103 are provided at each station. At each station, the camera 102 images the characteristics of the substrate 104 and at least one solder joint or boundary between the wire 103 and the substrate 104. The controller 170 determines a series of steps to efficiently solder the wire 103 to the substrate 104. Once the solder joint is complete, the controller 170 moves the holder 140 and soldering mechanism 122 to the next wire 103. Once all of the wires 103 are soldered to the substrate 104, the controller 170 moves the camera 102, holder 140 and soldering mechanism 122 to the next station. The controller 170 may plan a different motion profile and fluid dispensing pattern at each station because the positioning of the wires 103 relative to the substrates 104 at each station may be different.

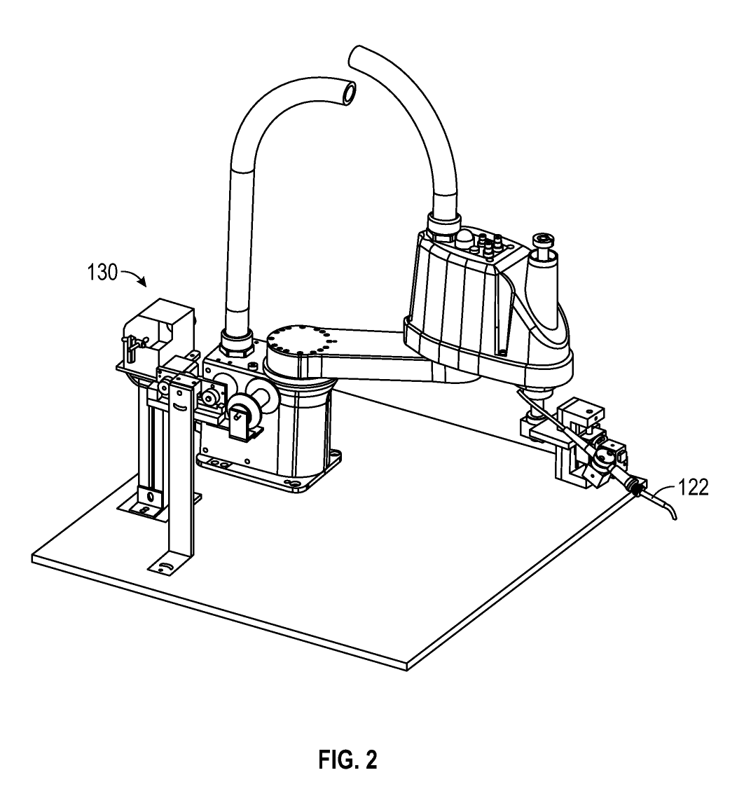

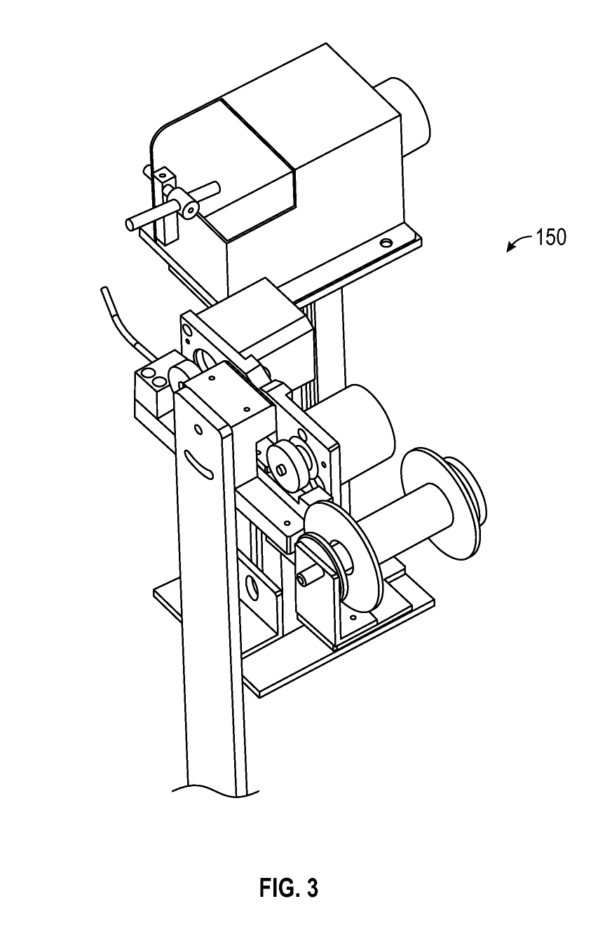

FIG. 2 is an enlarged view of the soldering mechanism 122 and soldering mechanism positioner 130. FIG. 3 is an enlarged view of the solder wire delivery mechanism 150.

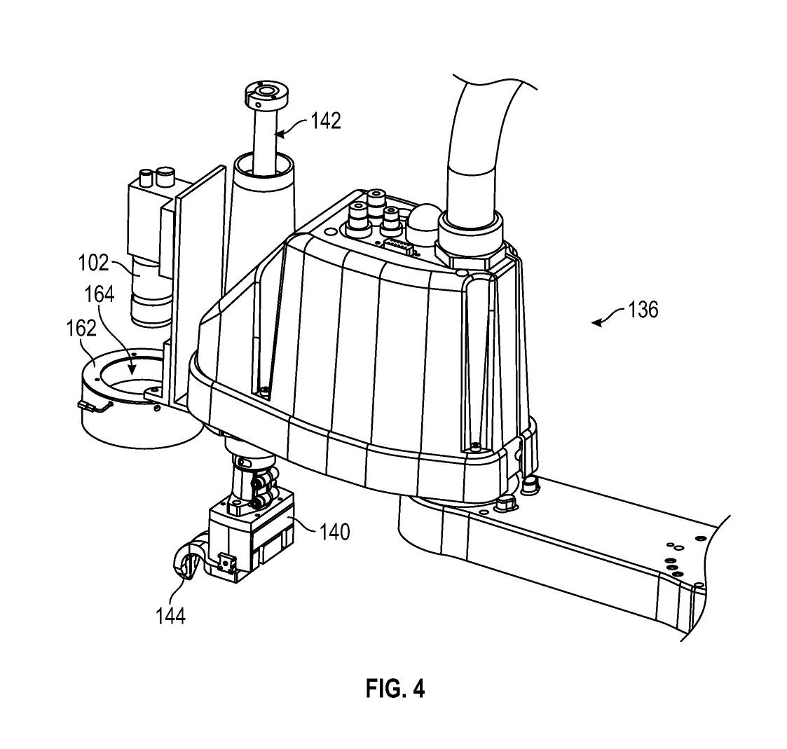

FIG. 4 is an enlarged view of the camera 102, a portion of the camera positioner 136, the holder 140 and the holder positioner 142. The camera 102 provides visual feedback for control of the machine. The camera 102 is positioned directly above an opening 164 in the optical component 162 and aimed through the opening 164. The opening 164 defines the field of view for the images taken by the camera 102. The holder 140 is positioned below the optical component 162. In an exemplary embodiment, the camera 102 is positioned directly above the finger 144 of the holder 140. The finger 144 may be configured to pinch the wire 103 (shown in FIG. 1) to hold the wire 103.

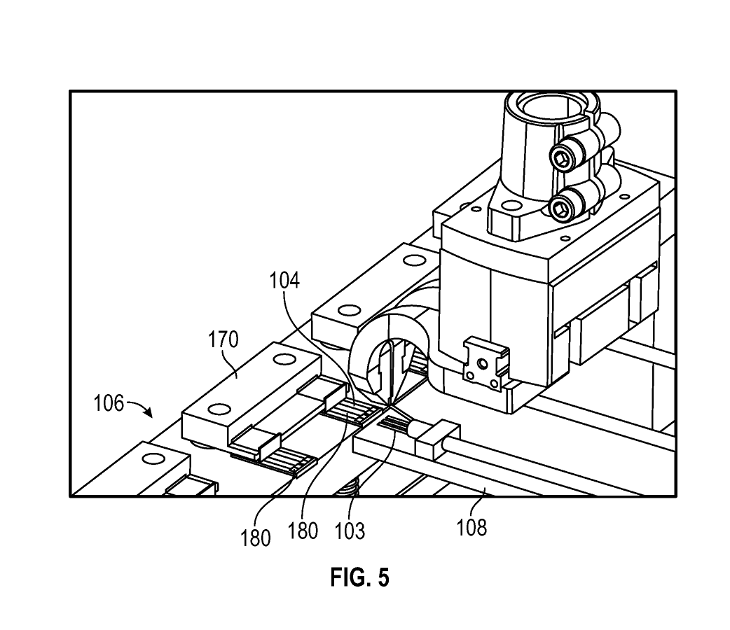

FIG. 5 illustrates the fixture 106 with a portion of the tray 108 (shown in FIG. 1) removed for clarity. The substrates 104 are held in place by holders 170. The tray 108 holds the wires 103 in position for soldering to the substrates 104. In an exemplary embodiment, the holder 140 is configured to grab one of the wires 103 and hold the wire 103 is position relative to the substrate 104 during the soldering process. In the illustrated embodiment, the substrates 104 each include conductive traces 180 on a surface of the substrate body. Engineering fluid, such as solder, may be applied to the conductive traces 180

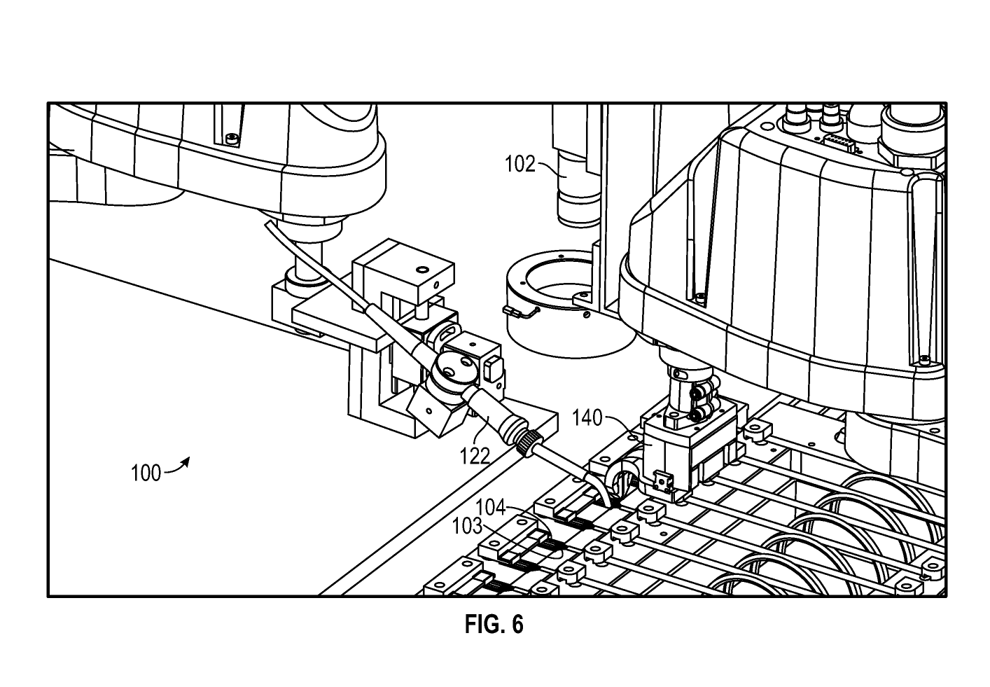

FIG. 6 is an enlarged view of a portion of the soldering machine 100 showing the soldering mechanism 122 soldering one of the wires to the corresponding substrate 104. The motion of the soldering mechanism 122, holder 140 and camera 102 is controlled by the controller 170 (shown in FIG. 1) based on the images taken by the camera 102 and/or other inputs from other cameras or sensors. For example, the camera 102 may be positioned directly vertically above the soldering mechanism 122 such that the camera 102 is capable of sensing and imaging the X and Y position of the soldering mechanism 122, but may have limited or no input regarding the Z (e.g. vertical) position. Another camera could provide information regarding the Z position, or alternatively, another sensor, such as a force sensor may provide input regarding the Z position, such as by sensing that the soldering mechanism 122 engages the solder, the substrate and/or the wire. The motion may be updated throughout the dispensing process. The motion of the soldering mechanism 122 is independent of the motion of the holder 140 and the camera 102.

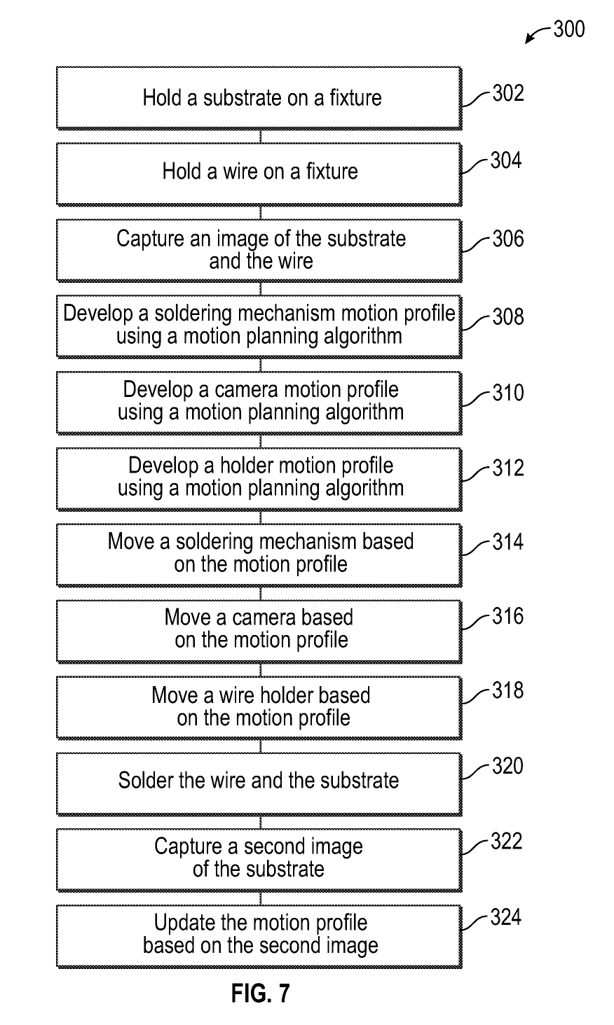

FIG. 7 illustrates a method 300 of soldering a wire to a substrate. At 302, the method includes holding a substrate on a fixture. For example, the substrate may be held by a spring loaded holder. The substrate is held such that portions of the substrate are exposed for processing. For example, conductive traces of the substrate may be exposed for applying engineering fluid (e.g. epoxy, adhesive, solder, plating, and the like) thereto. The conductive traces are exposed for soldering a wire thereto.

At 304, the method includes holding a wire on a fixture. For example, the wire may be held by a tray. The tray may be held by the fixture. A plurality of wires may be held in relative proximity to the substrate for soldering thereto.

At 306, the method includes capturing an image of a substrate and wire, such as at a solder joint. The image may be captured by a camera aimed at the soldering zone. The camera views the characteristics of the wire, the substrate, the solder, and the solder joint. The camera may capture more than one image. Multiple cameras may be provided to view different portions or angles of the soldering zone. Optionally, the soldering zone may be illuminated by an illumination source. The substrate and wire may be illuminated by lights of different wavelengths. Different portions of the substrate may be affected differently by the different wavelength lights, such as to distinguish boundaries.

At 308, the method includes developing a soldering mechanism motion profile for the soldering machine. The soldering mechanism motion profile controls movement of a soldering mechanism used during the soldering process. The soldering mechanism motion profile includes a set of instructions executable by a computer to control operation of the soldering machine. In an exemplary embodiment, the soldering machine includes a controller for controlling operation of the soldering machine. The controller includes a motion planning algorithm that determines how the soldering mechanism should be moved relative to the substrate and wire for performing the soldering operation. The controller may distinguish between the different boundaries. For example, when the substrate is illuminated by lights of different wavelength, the controller may determine boundaries between the different materials using recognition software. In an exemplary embodiment, the controller determines the shape and arrangement of the wires relative to the conductive traces. Data from the image is used to generate the soldering mechanism motion profile and the soldering machine is operated according to the motion profile. Optionally, the soldering mechanism motion profile may be updated and corrected for after or during soldering.

At 310, the method includes developing a camera motion profile for the soldering machine. The camera motion profile controls movement of a camera used to visualize the soldering mechanism, wire and substrate during the soldering process. The camera motion profile includes a set of instructions executable by a computer to control operation of the soldering machine. In an exemplary embodiment, the soldering machine includes a controller for controlling operation of the soldering machine. The controller includes a motion planning algorithm that determines how the camera should be moved relative to the substrate and wire for visualizing the soldering operation. The controller may determine the location of the next station to move the camera to after a soldering operation.

At 312, the method includes developing a holder motion profile for the soldering machine. The holder motion profile controls movement of a holder used for holding the wire during the soldering process. The holder motion profile includes a set of instructions executable by a computer to control operation of the soldering machine. In an exemplary embodiment, the soldering machine includes a controller for controlling operation of the soldering machine. The controller includes a motion planning algorithm that determines how the holder should be moved relative to the substrate to position and hold the wire during the soldering operation. The holder may move the position of the wire during the soldering operation based on images captured by the camera during the soldering operation. Data from the image is used to generate the holder motion profile and the soldering machine is operated according to the motion profile. Optionally, the holder motion profile may be updated and corrected for after or during soldering.

At 314, the method includes moving the soldering mechanism based on the motion profile. For example, the soldering machine may include soldering mechanism positioners that move the soldering mechanism relative to the fixture. At 316, the method includes moving the camera based on the motion profile. For example, the soldering machine may include camera positioners that move the camera relative to the fixture. At 318, the method includes moving the wire holder based on the motion profile. For example, the wire holder may include holder positioners that move the holder relative to the fixture.

At 320, the method includes soldering the wire and the substrate. As the soldering mechanism is moved along the motion profile, the controller controls the soldering parameters, such as by adjusting the energy applied by the soldering mechanism, adjusting the time the soldering mechanism is at a particular location or the rate at which the soldering mechanism is moved.

At 322, in some embodiments, the method may include capturing a second image of the wire, substrate and solder joint. The second image may be captured after or during soldering. At 324, the motion profiles may be updated, such as based on the second image. Updating of the motion profile ensures high quality soldering.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A soldering machine comprising:
a frame;
a fixture held by the frame, the fixture being configured to support a substrate and a cable with individual wires configured to be soldered to conductive traces of the substrate;
a guidance system supported by the frame, the guidance system having a camera viewing the fixture, the camera being movable relative to the fixture;
a positioning system supported by the frame, the positioning system having a camera positioner and a soldering mechanism positioner, the camera being coupled to and movable by the camera positioner relative to the fixture;
a soldering mechanism coupled to the soldering mechanism positioner and moved by the soldering mechanism positioner relative to the fixture, the soldering mechanism being configured to solder the wires to the conductive traces of the substrate; and
a controller communicating with the positioning system and the guidance system, the controller operating the positing system to control a position of the camera and a position of the soldering mechanism relative to the fixture based on an image obtained by the camera.

2. The soldering machine of claim 1, wherein the camera is configured to image a solder area where the soldering mechanism solders the wire to the conductive trace, the controller using vision guidance from images captured by the camera to control a position of the soldering mechanism.

3. The soldering machine of claim 1, wherein the controller develops a motion profile for the positioning system to move the soldering mechanism.

4. The soldering machine of claim 1, wherein the controller develops a motion profile for the positioning system to move the soldering mechanism, the motion profile being updated based on images taken by the camera during soldering.

5. The soldering machine of claim 1, wherein the controller develops a motion profile for the positioning system to move the camera positioner independently of the soldering mechanism positioner.

6. The soldering machine of claim 1, further comprising a holder configured to hold at least one of the substrate and the wires, the positioning system comprising a holder positioner for moving the holder relative to the fixture, the holder being movable relative to the soldering mechanism.

7. The soldering machine of claim 1, wherein the camera images the substrate and wires in a soldering zone during operation of the soldering mechanism, the controller causing the positioning system to move the soldering mechanism based on images generated during operation of the soldering mechanism.

8. The soldering machine of claim 7, wherein the controller updates operation of the positioning system based on the new image of the soldering zone.

9. The soldering machine of claim 1, wherein the soldering mechanism positioner control a position of the soldering mechanism in 3D space, and wherein the camera positioner control a position of the camera in 2D space along a horizontal plane.

10. The soldering machine of claim 1, wherein the guidance system includes an optical component affecting an image taken by the camera.

11. The soldering machine of claim 1, wherein the guidance system includes an optical component, the optical component having an illumination source emitting light at different wavelengths on the substrate and wires, the controller differentiating a boundary between the wire and the substrate based on the light emitted by the illumination source.

12. The soldering machine of claim 1, wherein the controller operates a boundary recognition algorithm determining a shape and position of the wire relative to the substrate, the controller determining a motion profile for moving the soldering mechanism based on the determined shape and positioning of the boundary.

13. A method of soldering a wire to a conductive trace of a substrate comprising:
holding the substrate on a fixture;
holding the wire relative to the substrate;
capturing an image of the wire and the substrate using a camera;
developing a motion profile based on the position of the wire and the substrate from the image using a controller; and
moving a soldering mechanism to solder the wire to the conductive trace on the substrate based on the motion profile.

14. The method of claim 13, wherein said developing a motion profile is based on a shape and a position of the wire and the conductive trace on the substrate.

15. The method of claim 13, wherein said developing a motion profile includes determining a boundary between the wire and the conductive trace, said moving a soldering mechanism comprises moving the soldering mechanism along the boundary.

16. The method of claim 13, wherein said developing a motion profile comprises developing a motion profile based on different intensity levels in the image.

17. The method of claim 13, wherein said capturing an image comprises illuminating the substrate with light of different wavelengths, the light affecting the substrate differently than the wires, said developing a motion profile comprises distinguishing a boundary between the wire and the substrate based on the illumination effects of the image.

18. The method of claim 13, further comprising capturing a second image of the substrate using the camera after the wire is at least partially soldered to the conductive trace and updating the motion profile based on the second image.

19. The method of claim 13, further comprising positioning the camera at a viewable location relative to the soldering mechanism, the substrate and the wire, the position of the camera being movable relative to the fixture.

20. The method of claim 13, further comprising coupling the camera to a movable camera positioner and coupling the soldering mechanism to a movable soldering mechanism positioner, said developing a motion profile comprises developing a motion profile for the camera positioner and developing a motion profile for the soldering mechanism positioner to allow independent movement of the soldering mechanism relative to the camera.
